(19) United States
(12) Patent Application Publication
(10) Pub. No.: US 2017/0170202 A1
(43) Pub. Date: Jun. 15, 2017

(54) MANUFACTURE METHOD OF TFT SUBSTRATE STRUCTURE AND TFT SUBSTRATE STRUCTURE

(71) Applicant: Wuhan China Star Optoelectronics Technology Co., Ltd., Wuhan City (CN)

(72) Inventors: Wenshuai Guo, Wuhan City (CN); Xing Ming, Wuhan City (CN); Zhiyuan Shen, Wuhan City (CN)

(21) Appl. No.: 14/778,606

(22) PCT Filed: Jun. 24, 2015
(86) PCT No.: PCT/CN2015/082163

§ 371 Date: Sep. 20, 2015

(30) Foreign Application Priority Data
Jun. 9, 2015 (CN) 201510313750.9

(51) Int. Cl. H01L 27/12; H01L 29/66; H01L 29/49; H01L 29/51; H01L 29/786; H01L 29/423

(52) U.S. Cl. CPC H01L 27/127; H01L 27/1222; H01L 29/78675; H01L 29/78621; H01L 29/78696; H01L 29/42384; H01L 29/4908; H01L 29/51; H01L 29/518; H01L 29/66757; H01L 29/66598

(57) ABSTRACT

The present invention provides a manufacture method of a TFT substrate structure and a TFT substrate structure. In the manufacture method of the TFT substrate structure according to the present invention, by adjusting the parameter of etching as manufacturing the gate, the angular surfaces are formed at the two sides of the gate, and the gate is used to be a mask to implement ion implantation to the polysilicon layer to form the n-type heavy doping area and the n-type light doping area are formed at the polysilicon layer at the same time. In the TFT structure according to the present invention, the polysilicon layer comprises n-type heavy doping areas at two sides and n-type light doping areas between the channel area of the polysilicon layer and the n-type heavy doping areas.

### FIELD OF THE INVENTION

The present invention relates to a display technology field, and more particularly to a manufacture method of a TFT substrate structure and a TFT substrate structure.

### BACKGROUND OF THE INVENTION

The LCD (Liquid Crystal Display) possesses many advantages of being ultra thin, power saved and radiation free. It has been widely utilized in, such as mobile phones, Personal Digital Assistant (PDAs), digital cameras, laptop screens or notebook screens.

Generally, the liquid crystal display comprises a shell, a LCD panel located in the shell and a backlight module located in the shell. Particularly, the structure of the liquid crystal panel mainly comprise a TFT Array Substrate (Thin Film Transistor Array Substrate), a CF (Color Filter) and a Liquid Crystal Layer. The working principle is that the light of backlight module is reflected to generate images by applying driving voltages to the two glass substrate for controlling the rotations of the liquid crystal molecules.

With the mobile display technology has been playing a significant role in the application of life, the development direction of the mobile display technology goes for higher display quality, high precision degree, thinner and lower power consumption. The size of the element is demanded to be smaller and smaller. The electric field strength in local area inside the element is also enhanced thereby, and particularly, a strong electrical field exists around the drain. Under the action of the strong electrical field, the carrier gains higher energy and becomes hot carrier. The influence of the hot carrier to the element property shows in the following two aspects:

(1) the hot carrier crossing the isolation layer is implanted into the oxide layer and accumulates constantly to change the threshold voltage, and thus affect the element lifetime.

(2) in the depletion region around the drain, new electron hole pairs are generated due to the collision with the crystal lattice. The Metal Oxide Semiconductor (MOS) field effect transistor is illustrated, the electrons generated by collision form the additional leakage electrical current, and holes are collected by the substrate to form the substrate current. The total current becomes a sum of saturated drain current and substrate current. The hot carrier effect is one of the fundamental factors restricting the highest working voltage of the element.

For solving the influence of the appearance of the hot carrier effect to the element property, the technical staff figures out kinds of methods to avoid the generation of the strong electrical field. Please refer to FIG. 1, which is a diagram of a manufacture method of a TFT substrate structure according to prior art. The TFT substrate structure comprises a substrate 100, a buffer layer 200 positioned on the substrate 100, a polysilicon layer 300 positioned on the buffer layer 200. The method utilizes the photoresist layer 600 to be a mask for implementing ion implantation to the polysilicon layer 300. Corresponding to the two sides of the gate, two symmetric n-type light doping areas (LDD) 320 are formed between the channel area 330 of the polysilicon layer 300 and the n-type heavy doping area 310 to disperse the strong electrical field around the electrode and reduce the generation of the hot carriers. However, it means that a solo mask design and one photolithographic process against the manufacture of the n-type light doping area 320 are required, which needs spend a lot of money.

### SUMMARY OF THE INVENTION

An objective of the present invention is to provide a manufacture method of a TFT substrate structure, capable of forming the n-type heavy doping area and the n-type light doping area at the polysilicon layer at the same time for increasing the resistance value and dispersing the strong electrical field around the electrode to avoid the influence of hot carrier effect to the element property due to the existence of the local strong electrical field.

Another objective of the present invention is to provide a TFT structure, of which the polysilicon layer comprises n-type heavy doping areas at two sides and n-type light doping areas between the channel area of the polysilicon layer and the n-type heavy doping areas to avoid the generation of the strong electrical field and eliminating the influence of hot carrier effect to the element property.

For realizing the aforesaid objectives, the present invention is to provide a manufacture method of a TFT substrate structure, comprising steps of:

step 1, providing a substrate and deposing a buffer layer on the substrate;

step 2, deposing a polysilicon layer on the buffer layer and deposing a gate isolation layer on the polysilicon layer;

step 3, deposing a metal layer on the gate isolation layer and patterning the metal layer to form a gate corresponding to a middle part of the polysilicon layer;

the gate is a trapezoid structure, comprising an upper bottom surface, a lower bottom surface, a first angular surface and a second angular surface which connect the upper bottom surface and the lower bottom surface the first angular surface and the second angular surface are oppositely positioned; an area of the upper bottom surface is smaller than an area of the lower bottom surface;

step 4, using the gate to be a mask, and employing ion implantation process to implement n-type doping to the polysilicon layer, and forming n-type heavy doping areas at two sides of the polysilicon layer which are not covered by the gate; forming a first n-type light doping area and a second n-type light doping area at the polysilicon layer corresponding to areas of the first angular surface and the second angular surface of the gate; and forming a channel area which is undoped at the middle part of the polysilicon layer corresponding to an area of the upper bottom surface of the gate.

A thickness of the gate is 2000 Å-8000 Å.

The first angular surface and the second angular surface in the step 3 are formed by dry etching or wet etching.

An included angle formed between the first angular surface and the lower bottom surface is 10°-60°; an included angle formed between the second angular surface and the lower bottom surface is 10°-60°.

N-type ion concentrations in the first and the second n-type light doping areas appear to be linearly decreasing distributed from outer side to inner side.

Material of the buffer layer, and the gate isolation layer is Silicon Oxide, Silicon Nitride or a combination of the two; material of the gate is a stack combination of one or more of molybdenum, titanium, aluminum and copper.

The present invention further provides a TFT substrate structure, comprising a substrate, a buffer layer positioned on the substrate, a polysilicon layer positioned on the buffer layer, a gate isolation layer positioned on the polysilicon layer, and a gate being positioned on the gate isolation layer and corresponding to a middle part of the polysilicon layer;

the gate is a trapezoid structure, comprising an upper bottom surface, a lower bottom surface, a first angular surface and a second angular surface which connect the upper bottom surface and the lower bottom surface; the first angular surface and the second angular surface are oppositely positioned; an area of the upper bottom surface is smaller than an area of the lower bottom surface;

the polysilicon layer comprises a channel area which is at the middle part and undoped and corresponds to the upper bottom surface, a first n-type light doping area and a second n-type light doping area respectively being positioned at two sides of the channel area, and two n-type heavy doping areas respectively being positioned at outer sides of the first n-type light doping area and the second n-type light doping area; the first n-type light doping area and the second n-type light doping area are respectively corresponding to the first angular surface and the second angular surface.

A thickness of the gate is 2000 Å-8000 Å; an included angle formed between the first angular surface and the lower bottom surface is 10°-60°; an included angle formed between the second angular surface and the lower bottom surface is 10°-60°.

N-type ion concentrations in the first and the second n-type light doping areas appear to be linearly decreasing distributed from outer side to inner side.

Material of the buffer layer, and the gate isolation layer is Silicon Oxide, Silicon Nitride or a combination of the two; material of the gate is a stack combination of one or more of molybdenum, titanium, aluminum and copper.

The present invention further provides a TFT substrate structure, comprising a substrate, a buffer layer positioned on the substrate, a polysilicon layer positioned on the buffer layer, a gate isolation layer positioned on the polysilicon layer, and a gate being positioned on the gate isolation layer and corresponding to a middle part of the polysilicon layer;

the gate is a trapezoid structure, comprising an upper bottom surface, a lower bottom surface, a first angular surface and a second angular surface which connect the upper bottom surface and the lower bottom surface; the first angular surface and the second angular surface are oppositely positioned; an area of the upper bottom surface is smaller than an area of the lower bottom surface;

the polysilicon layer comprises a channel area which is at the middle part and undoped and corresponds to the upper bottom surface, a first n-type light doping area and a second n-type light doping area respectively being positioned at two sides of the channel area, and two n-type heavy doping areas respectively being positioned at outer sides of the first n-type light doping area and the second n-type light doping area; the first n-type light doping area and the second n-type light doping area are respectively corresponding to the first angular surface and the second angular surface;

wherein a thickness of the gate is 2000 Å-8000 Å; an included angle formed between the first angular surface and the lower bottom surface is 10°-60°; an included angle formed between the second angular surface and the lower bottom surface is 10°-60°;

wherein n-type ion concentrations in the first and the second n-type light doping areas appear to be linearly decreasing distributed from outer side to inner side;

wherein material of the buffer layer, and the gate isolation layer is Silicon Oxide, Silicon Nitride or a combination of the two; material of the gate is a stack combination of one or more of molybdenum, titanium, aluminum and copper.

The benefits of the present invention are: in the manufacture method of the TFT substrate structure according to the present invention, by adjusting the parameter of etching as manufacturing the gate, the angular surfaces are formed at the two sides of the gate, and the gate is used to be a mask to implement ion implantation to the polysilicon layer to form the n-type heavy doping area and the n-type light doping area are formed at the polysilicon layer at the same time for increasing the resistance value and dispersing the strong electrical field around the electrode. The influence of hot carrier effect to the element property due to the existence of the local strong electrical field, and the other influence to the element due to the asymmetric light doping area can be avoided to eliminate the process of solo forming n-type light doping area for raising the generating efficiency and reducing the production cost. In the TFT substrate structure according to the present invention, the polysilicon layer comprises n-type heavy doping areas at two sides and n-type light doping areas between the channel area of the polysilicon layer and the n-type heavy doping areas to avoid the generation of the strong electrical field and eliminating the influence of hot carrier effect to the element property.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a diagram of a manufacture method of a TFT substrate structure according to prior art;

FIG. 2 is a flowchart of a manufacture method of a TFT substrate structure according to the present invention;

FIG. 3 is a diagram of the step 1 in the manufacture method of the TFT substrate structure according to the present invention;

FIG. 4 is a diagram of the step 2 in the manufacture method of the TFT substrate structure according to the present invention;

FIG. 5 is a diagram of the step 3 in the manufacture method of the TFT substrate structure according to the present invention;

FIG. 6 is a diagram of the step 4 in the manufacture method of the TFT substrate structure according to the present invention;

FIG. 7 is a sectional diagram of a TFT substrate structure according to the present invention.

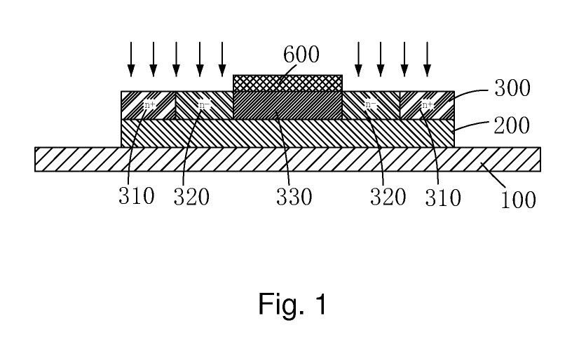

### DETAILED DESCRIPTION OF PREFERRED EMBODIMENTS

For better explaining the technical solution and the effect of the present invention, the present invention will be further described in detail with the accompanying drawings and the specific embodiments.

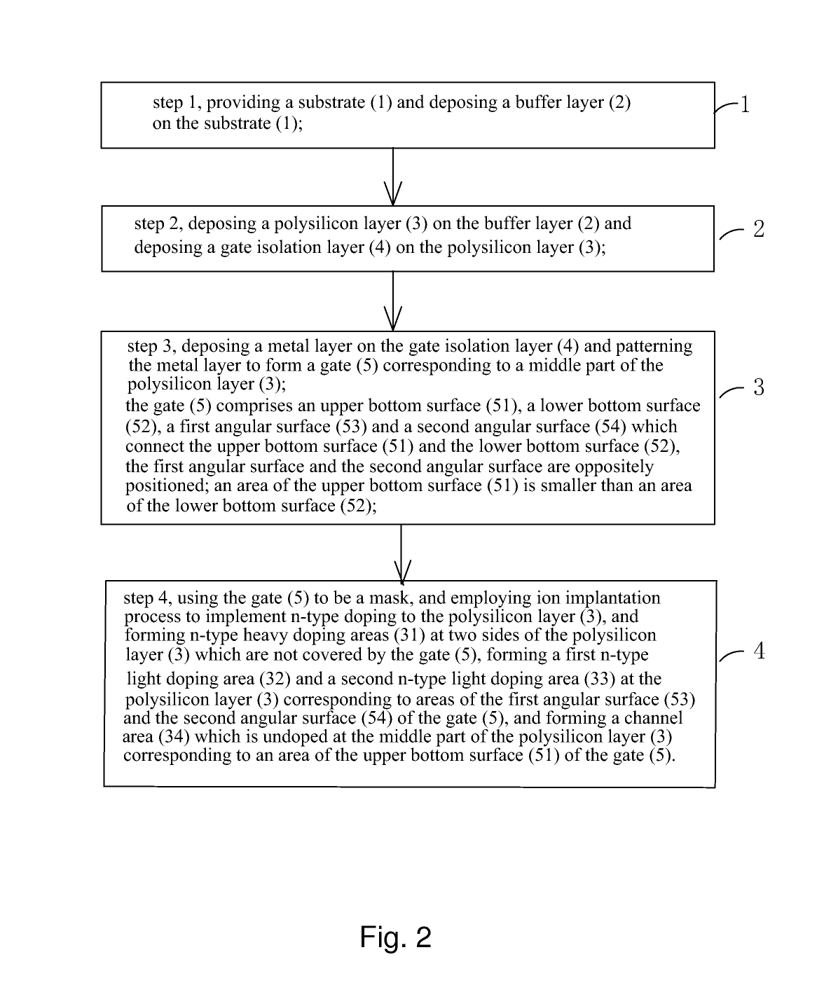

Please refer to FIG. 2. The present invention first provides a manufacture method of a TFT substrate structure, comprising steps of:

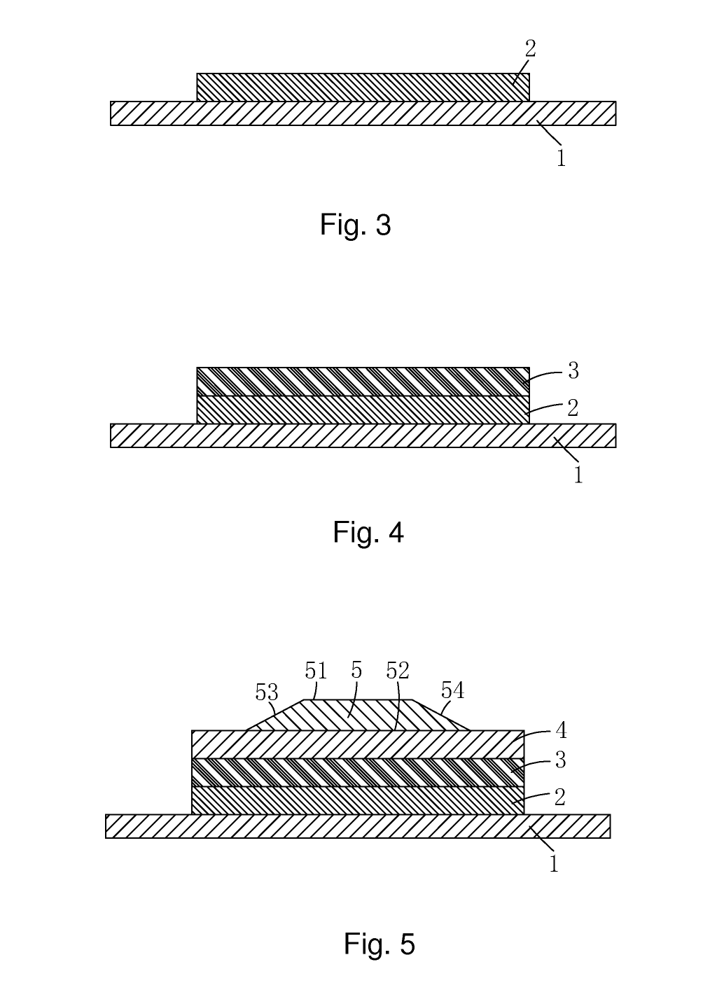

step 1, as shown in FIG. 3, providing a substrate 1 and deposing a buffer layer 2 on the substrate 1.

Specifically, the substrate 1 can be a glass substrate or a plastic substrate, and material of the buffer layer 2 can be Silicon Oxide (SiOx), Silicon Nitride (SiNx) or a combination of the two.

step 2, as shown in FIG. 4, deposing a polysilicon (Poly-Si) layer 3 on the buffer layer 2 and deposing a gate isolation layer 4 on the polysilicon layer 3.

Specifically, material of the gate isolation layer 4 can be Silicon Nitride, Silicon Oxide, or a combination of the two.

step 3, as shown in FIG. 5, deposing a metal layer on the gate isolation layer 4 and patterning the metal layer to form a gate 5 corresponding to a middle part of the polysilicon layer 3.

The gate 5 is a trapezoid structure, comprising an upper bottom surface 51, a lower bottom surface 52, a first angular surface 53 and a second angular surface 54 which connect the upper bottom surface 51 and the lower bottom surface 52; the first angular surface 53 and the second angular surface 54 are oppositely positioned; an area of the upper bottom surface 51 is smaller than an area of the lower bottom surface 52.

Specifically, an included angle formed between the first angular surface 53 and the lower bottom surface 52 is 10°-60°; an included angle formed between the second angular surface 54 and the lower bottom surface 52 is 10°-60°.

Preferably, the included angles formed between the first angular surface 53, the second angular surface 54 and the lower bottom surface 52 are the same.

Specifically, material of the gate 5 can be a stack combination of one or more of molybdenum (Mo), titanium (Ti), aluminum (Al) and copper (Cu).

Specifically, the first angular surface 53 and the second angular surface 54 are formed by dry etching (Dry Etch) or wet etching (Wet Etch), and by adjusting the parameter of etching process the included angles formed between the first angular surface 53, the second angular surface 54 and the lower bottom surface 52 can be adjusted.

Preferably, a thickness of the gate 5 is 2000 Å-8000 Å.

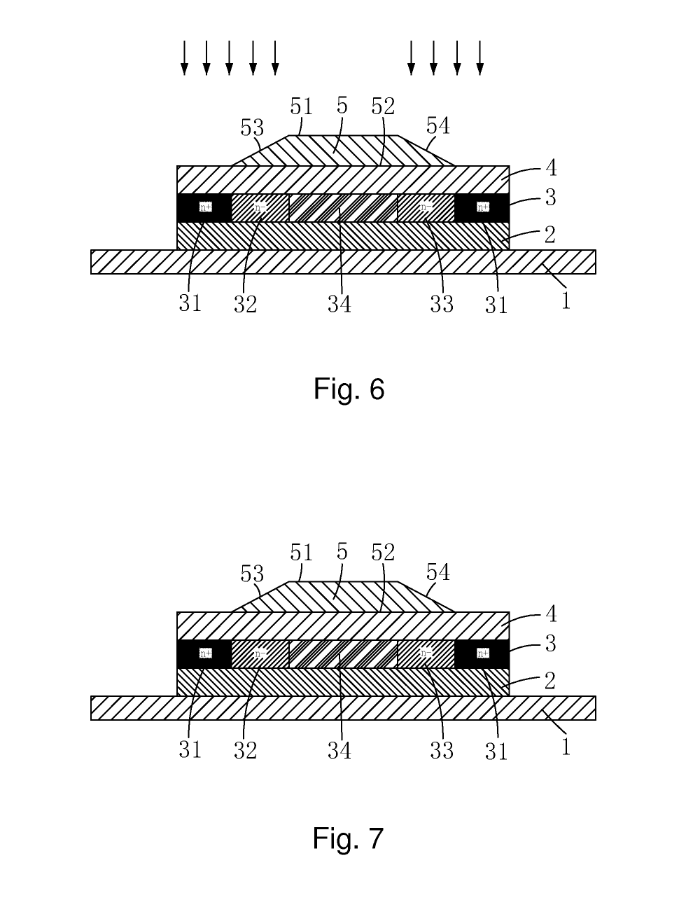

step 4, as shown in FIG. 6, using the gate 5 to be a mask, and employing ion implantation process to implement n-type doping to the polysilicon layer 3, and forming n-type heavy doping areas 31 at two sides of the polysilicon layer 3 which are not covered by the gate 5; forming a first n-type light doping area 32 and a second n-type light doping area 33 at the polysilicon layer 3 corresponding to areas of the first angular surface 53 and the second angular surface 54 of the gate 5; and forming a channel area 34 which is undoped at the middle part of the polysilicon layer 3 corresponding to an area of the upper bottom surface 51 of the gate 5.

Because the two sides of the gate 5 are gentle angular surfaces, and thus in the process of employing ion implantation process to implement n-type doping to the polysilicon layer 3, the n-type heavy doping areas 31 are formed in the area which are not covered by the gate 5. Because the thickness of the gate 5 at the first angular surface 53 and the second angular surface 54 is thinner, the n-type ions can penetrate the gate 5, and the first and the second n-type light doping areas 32, 33, of which n-type ion concentrations appear to be linearly decreasing distributed can be formed in the area the polysilicon layer 3 where is covered by the first angular surface 53, the second angular surface 54 of the gate 5. The first and the second n-type light doping areas 32, 33 increase the resistance value and disperse the strong electrical field around the electrode to avoid the influence of hot carrier effect to the element property due to the existence of the local strong electrical field.

Furthermore, the thickness of the gate 5 between the first angular surface 53 and the lower bottom surface 52 appears to be linearly increasing from outer side to inner side, and thus, as implementing n-type doping, the difficulty of n-type ion implantation also increases from outer side to inner side. Accordingly, the n-type ion concentration of the ultimately acquired first n-type light doping area 32 is linearly decreasing distributed from outer side to inner side.

Similarly, the thickness of the gate 5 between the second angular surface 54 and the lower bottom surface 52 appears to be linearly increasing from outer side to inner side, and thus, as implementing n-type doping, the difficulty of n-type ion implantation also increases from outer side to inner side. Accordingly, the n-type ion concentration of the ultimately acquired second n-type light doping area 33 is linearly decreasing distributed from outer side to inner side.

Specifically, the range of the n-type ion concentration Cₙ₊ of the n-type heavy doping areas 31 obtained in the step 4 is 10¹⁴-10¹⁵ions/cm³; the range of the n-type ion concentration Cₙ₋ of the first n-type light doping area 32, second n-type light doping area 33 is Cₙ₊>Cₙ₋>0.

In the manufacture method of the TFT substrate structure according to the present invention, by respectively arranging two n-type light doping areas at the two sides of the channel, the other influence to the element due to the asymmetric light doping area can be avoided.

In the aforesaid manufacture method of the TFT substrate structure, by adjusting the parameter of etching process as manufacturing the gate, the angular surfaces are formed at the two sides of the gate, and the gate is used to be a mask to implement ion implantation to the polysilicon layer, and meanwhile, the n-type heavy doping area and the n-type light doping area of linear ion concentration are formed at the polysilicon layer at the same time in one single manufacture process for increasing the resistance value and dispersing the strong electrical field around the electrode. The influence of hot carrier effect to the element property due to the existence of the local strong electrical field, and the other influence to the element due to the asymmetric light doping area can be avoided to eliminate the process of solo forming n-type light doping area for raising the generating efficiency and reducing the production cost.

Please refer to FIG. 7. The present invention further provides a TFT substrate structure, comprising a substrate 1, a buffer layer 2 positioned on the substrate 1, a polysilicon layer 3 positioned on the buffer layer 2, a gate isolation layer 4 positioned on the polysilicon layer 3, and a gate 5 being positioned on the gate isolation layer 4 and corresponding to a middle part of the polysilicon layer 3.

The gate 5 is a trapezoid structure, comprising an upper bottom surface 51, a lower bottom surface 52, a first angular surface 53 and a second angular surface 54 which connect the upper bottom surface 51 and the lower bottom surface 52; the first angular surface 53 and the second angular surface 54 are oppositely positioned; an area of the upper bottom surface 51 is smaller than an area of the lower bottom surface 52.

The polysilicon layer 3 comprises a channel area 34 which is at the middle part and undoped and corresponds to the upper bottom surface 51, a first n-type light doping area 32 and a second n-type light doping area 33 respectively being positioned at two sides of the channel area 34, and two n-type heavy doping areas 31 respectively being positioned at outer sides of the first n-type light doping area 32 and the second n-type light doping area 33; the first n-type light doping area 32 and the second n-type light doping area 33 are respectively corresponding to the first angular surface 53 and the second angular surface 54.

Preferably, a thickness of the gate 5 is 2000 Å-8000 Å.

Specifically, an included angle formed between the first angular surface 53 and the lower bottom surface 52 is 10°-60°; an included angle formed between the second angular surface 54 and the lower bottom surface 52 is 10°-60°.

Preferably, the included angles formed between the first angular surface 53, the second angular surface 54 and the lower bottom surface 52 are the same.

Specifically, n-type ion concentrations in the first and the second n-type light doping areas 32, 33 appear to be linearly decreasing distributed.

Furthermore, the n-type ion concentrations in the first and the second n-type light doping areas 32, 33 appear to be linearly decreasing distributed from outer side to inner side.

Specifically, the range of the n-type ion concentration Cₙ₊of the n-type heavy doping areas 31 is 10¹⁴-10¹⁵ions/cm³; the range of the n-type ion concentration Cₙ₋ of the first n-type light doping area 32, second n-type light doping area 33 is Cₙ₊>Cₙ₋>0.

Specifically, material of the buffer layer 2, and the gate isolation layer 4 is Silicon Oxide, Silicon Nitride or a combination of the two; material of the gate 5 is a stack combination of one or more of molybdenum, titanium, aluminum and copper.

In the aforesaid TFT substrate structure, the polysilicon layer comprises n-type heavy doping areas at two sides and n-type light doping areas between the channel area of the polysilicon layer and the n-type heavy doping areas to avoid the generation of the strong electrical field and eliminating the influence of hot carrier effect to the element property.

In conclusion, in the manufacture method of the TFT substrate structure according to the present invention, by adjusting the parameter of etching as manufacturing the gate, the angular surfaces are formed at the two sides of the gate, and the gate is used to be a mask to implement ion implantation to the polysilicon layer, and meanwhile, the n-type heavy doping area and the n-type light doping area are formed at the polysilicon layer at the same time with one single manufacture process for increasing the resistance value and dispersing the strong electrical field around the electrode. The influence of hot carrier effect to the element property due to the existence of the local strong electrical field, and the other influence to the element due to the asymmetric light doping area can be avoided to eliminate the process of solo forming n-type light doping area for raising the generating efficiency and reducing the production cost. In the TFT substrate structure according to the present invention, the polysilicon layer comprises n-type heavy doping areas at two sides and n-type light doping areas between the channel area of the polysilicon layer and the n-type heavy doping areas to avoid the generation of the strong electrical field and eliminating the influence of hot carrier effect to the element property.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of a TFT substrate structure, comprising steps of:
step 1, providing a substrate and deposing a buffer layer on the substrate;
step 2, deposing a polysilicon layer on the buffer layer and deposing a gate isolation layer on the polysilicon layer;
step 3, deposing a metal layer on the gate isolation layer and patterning the metal layer to form a gate corresponding to a middle part of the polysilicon layer;
the gate is a trapezoid structure, comprising an upper bottom surface, a lower bottom surface, a first angular surface and a second angular surface which connect the upper bottom surface and the lower bottom surface;
the first angular surface and the second angular surface are oppositely positioned; an area of the upper bottom surface is smaller than an area of the lower bottom surface;
step 4, using the gate to be a mask, and employing ion implantation process to implement n-type doping to the polysilicon layer, and forming n-type heavy doping areas at two sides of the polysilicon layer which are not covered by the gate; forming a first n-type light doping area and a second n-type light doping area at the polysilicon layer corresponding to areas of the first angular surface and the second angular surface of the gate; and forming a channel area which is undoped at the middle part of the polysilicon layer corresponding to an area of the upper bottom surface of the gate.

2. The manufacture method of the TFT substrate structure according to claim 1, wherein a thickness of the gate is 2000 Å-8000 Å.

3. The manufacture method of the TFT substrate structure according to claim 1, wherein the first angular surface and the second angular surface in the step 3 are formed by dry etching or wet etching.

4. The manufacture method of the TFT substrate structure according to claim 1, wherein an included angle formed between the first angular surface and the lower bottom surface is 10°-60°; an included angle formed between the second angular surface and the lower bottom surface is 10°-60°.

5. The manufacture method of the TFT substrate structure according to claim 1, wherein n-type ion concentrations in the first n-type light doping area and in the second n-type light doping area appear to be linearly decreasing distributed from outer side to inner side.

6. The manufacture method of the TFT substrate structure according to claim 1, wherein material of the buffer layer and the gate isolation layer is Silicon Oxide, Silicon Nitride or a combination of the two; material of the gate is a stack combination of one or more of molybdenum, titanium, aluminum and copper.

7. A TFT substrate structure, comprising a substrate, a buffer layer positioned on the substrate, a polysilicon layer positioned on the buffer layer, a gate isolation layer positioned on the polysilicon layer, and a gate being positioned on the gate isolation layer and corresponding to a middle part of the polysilicon layer;
the gate is a trapezoid structure, comprising an upper bottom surface, a lower bottom surface, a first angular surface and a second angular surface which connect the upper bottom surface and the lower bottom surface;
the first angular surface and the second angular surface are oppositely positioned; an area of the upper bottom surface is smaller than an area of the lower bottom surface;
the polysilicon layer comprises a channel area which is at the middle part and undoped and corresponds to the upper bottom surface, a first n-type light doping area and a second n-type light doping area respectively being positioned at two sides of the channel area, and two n-type heavy doping areas respectively being positioned at outer sides of the first n-type light doping area and the second n-type light doping area; the first n-type light doping area and the second n-type light doping area are respectively corresponding to the first angular surface and the second angular surface.

8. The TFT substrate structure according to claim 7, wherein a thickness of the gate is 2000 Å-8000 Å; an included angle formed between the first angular surface and the lower bottom surface is 10°-60°; an included angle formed between the second angular surface and the lower bottom surface is 10°-60°.

9. The TFT substrate structure according to claim 7, wherein n-type ion concentrations in the first n-type light doping area and in the second n-type light doping area appear to be linearly decreasing distributed from outer side to inner side.

10. The TFT substrate structure according to claim 7, wherein material of the buffer layer, and the gate isolation layer is Silicon Oxide, Silicon Nitride or a combination of the two; material of the gate is a stack combination of one or more of molybdenum, titanium, aluminum and copper.

11. A TFT substrate structure, comprising a substrate, a buffer layer positioned on the substrate, a polysilicon layer positioned on the buffer layer, a gate isolation layer positioned on the polysilicon layer, and a gate being positioned on the gate isolation layer and corresponding to a middle part of the polysilicon layer;
the gate is a trapezoid structure, comprising an upper bottom surface, a lower bottom surface, a first angular surface and a second angular surface which connect the upper bottom surface and the lower bottom surface; the first angular surface and the second angular surface are oppositely positioned; an area of the upper bottom surface is smaller than an area of the lower bottom surface;
the polysilicon layer comprises a channel area which is at the middle part and undoped and corresponds to the upper bottom surface, a first n-type light doping area and a second n-type light doping area respectively being positioned at two sides of the channel area, and two n-type heavy doping areas respectively being positioned at outer sides of the first n-type light doping area and the second n-type light doping area; the first n-type light doping area and the second n-type light doping area are respectively corresponding to the first angular surface and the second angular surface;
wherein a thickness of the gate is 2000 Å-8000 Å; an included angle formed between the first angular surface and the lower bottom surface is 10°-60°; an included angle formed between the second angular surface and the lower bottom surface is 10°-60°;
wherein n-type ion concentrations in the first n-type light doping area and in the second n-type light doping area appear to be linearly decreasing distributed from outer side to inner side;
wherein material of the buffer layer, and the gate isolation layer is Silicon Oxide, Silicon Nitride or a combination of the two; material of the gate is a stack combination of one or more of molybdenum, titanium, aluminum and copper.
